(19) United States
(12) Patent Application Publication
(10) Pub. No.: US 2020/0083026 A1
(43) Pub. Date: Mar. 12, 2020

(54) PLASMA PROCESSING DEVICE

(71) Applicant: Hitachi High-Technologies Corporation, Tokyo (JP)

(72) Inventors: Takamasa ICHINO, Tokyo (JP); Kohei SATO, Tokyo (JP); Kazunori NAKAMOTO, Tokyo (JP); Kenetsu YOKOGAWA, Tokyo (JP)

(21) Appl. No.: 16/561,785

(22) Filed: Sep. 5, 2019

(30) Foreign Application Priority Data
Sep. 6, 2018 (JP) 2018-166773

(51) Int. Cl. H01J 37/32; H01L 21/67; H01L 21/683

(52) U.S. Cl. CPC H01J 37/32568; H01J 37/32715; H01J 37/32201; H01J 37/32311; H01J 37/3255; H01J 2237/3343; H01J 37/3266; H01L 21/67069; H01L 21/6833; H01J 37/32302; H01J 37/32513

(57) ABSTRACT

A plasma processing device in which plasma processing uniformity is improved up to an outer peripheral portion of a wafer and the number of non-defective devices that can be manufactured from one wafer is increased. The plasma processing device includes a vacuum container; a mounting table, a susceptor ring that covers an outer peripheral portion of an electrode base material, and an insulation ring covered by the susceptor ring and surrounding the electrode base material, and thin film electrode formed on an upper surface and a part of a surface facing the outer periphery of the electrode base material; a first high frequency power applied to the electrode base material a second high frequency power applied to the thin film electrode; a plasma generating unit that generates plasma on an upper portion of the mounting table inside the vacuum container; and a control unit.

### BACKGROUND OF THE INVENTION

The present invention relates to a plasma processing device, and particularly to a plasma processing device that generates plasma and etches a semiconductor substrate or the like.

With improvement of an integration degree of a semiconductor device, a circuit structure is miniaturized and a manufacturing process is complicated. Under such a circumstance, in order to control an increase in a unit price of the semiconductor device, it is required to increase a yield of a semiconductor device obtained from one wafer and it is required that a semiconductor device with good performance up to an outer peripheral edge of a wafer subject to processing can be manufactured with a high yield.

Corresponding to such a requirement, in a plasma processing device, performance of a semiconductor device formed on a wafer subject to processing which is processed by the plasma processing device is required to be uniform from a center to a peripheral portion in a surface of the wafer subject to processing.

With miniaturization of a circuit pattern, processing uniformity in a precision of nanometer and sub-nanometer order is required in an etching device which is a plasma processing device. Thus, in order to ensure the processing uniformity in the precision of nanometer and sub-nanometer order throughout an entire surface of the wafer subject to processing, it is important to improve a plasma processing precision in a vicinity of an outer peripheral portion of the wafer subject to processing where processing precision is likely to be reduced.

In an etching processing device, in the vicinity of the outer peripheral portion of the wafer subject to processing, an etching processing characteristic such as a precision of a machining shape of a pattern to be processed is likely to have a large variation in the vicinity of the outer peripheral portion with respect to the central portion of the wafer subject to processing, caused by an electromagnetic factor and a thermodynamic factor. The above problem is more significant as a size (outer diameter) of the wafer subject to processing increases. As a result, a machining shape in a vicinity of an outer peripheral portion of a wafer subject to processing which is processed by plasma etching may exceed a variation allowable range with respect to a machining precision in a vicinity of a central portion, and a semiconductor device formed in a vicinity of the outer peripheral portion of the wafer subject to processing cannot be shipped as a product.

As a method used to prevent such a case where the machining shape in the vicinity of the outer peripheral portion of the wafer subject to processing exceeds a variation allowable range with respect to the machining precision in the vicinity of the central portion, JP-A-2014-17292 (Patent Literature 1) discloses a plasma processing device capable of reducing an influence caused by a change in high frequency bias power, improving a machining characteristic in a vicinity of an outer peripheral portion of a wafer subject to processing, and improving processing uniformity by providing a high frequency ring having the same potential with a substrate electrode around the substrate electrode where a wafer subject to processing is loaded.

JP-A-2016-225376 (Patent Literature 2) discloses a configuration in which a conductor ring in a state of being electrically insulated from a base material of a sample stage is provided around the base material of the sample stage where a wafer subject to processing is loaded, and high frequency power is supplied to the conductor ring from a power supply different from high frequency power applied to the base material of the sample stage.

In the etching processing device, when the wafer subject to processing is processed by plasma, a shape of an electric field formed in the vicinity of the outer peripheral portion of the substrate electrode where the wafer subject to processing is mounted influences plasma processing uniformity. In the method disclosed in Patent Literature 1, in order to make the substrate electrode at the same potential with the high frequency ring, even an electric field formed in the vicinity of the outer peripheral portion of the substrate electrode can be adjusted to an ideal state when the high frequency power applied to the substrate electrode is in a certain condition, when the condition of the high frequency power applied to the substrate electrode is changed, it is difficult to adjust the electric field formed in the vicinity of the outer peripheral portion of the substrate electrode by the high frequency ring and it is difficult to uniformly process the wafer subject to processing up to the vicinity of the outer peripheral portion.

On the other hand, when the electric field at the outer peripheral portion of the wafer is distorted, non-uniformity or a shape irregularity occurs on an equipotential surface of an electric field formed in a sheath region at a boundary between a surface of the wafer and a plasma region above the wafer. In the sheath region, since ions receive a force in a direction perpendicular to the equipotential surface, when the equipotential surface is inclined with respect to a surface of the wafer, the ions which enter onto the wafer enter onto the wafer in a state of receiving a force in an oblique direction corresponding to an inclination of the equipotential surface. As a result, there may be problems such as a distribution occurs in shapes of patterns formed on the wafer and consumption of a ring formed of an insulator on the outer peripheral portion of the wafer is accelerated.

In contrast, in order to correct the inclination of the electric field in the sheath region that occurs on the outer peripheral portion of the base material (substrate electrode) of the sample stage, in the configuration disclosed in Patent Literature 2, a conductor ring (high frequency ring electrode) is provided on the insulation ring disposed on the outer peripheral portion of the base material of the sample stage, and controlled high frequency power different from the high frequency power supplied to the base material of the sample stage is supplied to the conductor ring.

However, when high frequency power from different power supply is respectively supplied to the conductor ring and the base material of the sample stage with a dielectric interposed therebetween, capacitive coupling generated between the base material of the sample stage and the conductor ring causes interference between the high frequency power applied to the base material of the sample stage and the high frequency power applied to the conductor ring, so that the high frequency power applied to the conductor ring having relatively low power cannot be controlled, and the electric field on the outer peripheral portion of the wafer which is mounted on the base material of the sample stage may be distorted.

### SUMMARY OF THE INVENTION

The invention solves problems in the prior art described above, and provides a plasma processing device capable of stably controlling high frequency power applied to a high frequency ring electrode even when high frequency power applied to a substrate electrode is changed, reducing an influence on plasma processing uniformity from a shape of an electric field formed in a sheath region in a vicinity of the outer peripheral portion of the substrate electrode, improving the plasma processing uniformity up to a vicinity of an outer peripheral portion of a wafer subject to processing, and increasing the number of non-defective devices that can be manufactured from one wafer.

To solve the problems described above, the invention provides a plasma processing device that includes a vacuum container; a mounting table that includes an electrode base material where a sample subject to processing is mounted inside the vacuum container, a susceptor ring that is formed of an insulating material that covers an outer peripheral portion of the electrode base material, and an insulation ring that is covered by the susceptor ring, is disposed to surround an outer periphery of the electrode base material, and has a thin film electrode formed on an upper surface and a part of a surface facing the outer periphery of the electrode base material; a first high frequency power applying unit that applies first high frequency power to the electrode base material of the mounting table; a second high frequency power applying unit that applies second high frequency power to the thin film electrode formed on the insulation ring; a plasma generating unit that generates plasma on an upper portion of the mounting table inside the vacuum container; and a control unit that controls the first high frequency power applying unit, the second high frequency power applying unit, and the plasma generating unit.

According to the invention, the plasma processing uniformity can be improved from a central portion to the vicinity of the outer periphery of the wafer subject to processing and the number of non-defective devices (yield of non-defective devices) that can be obtained from one wafer can be increased.

Further, according to the invention, life of a ring-shaped member disposed on the outer peripheral portion of the wafer can be prolonged, and a device operation rate of the plasma processing device can be increased by reducing frequency of component replacement.

### BRIEF DESCRIPTION OF THE DRAWINGS

FIG. 1 is a block diagram illustrating a schematic configuration of a plasma processing device according to an embodiment of the invention.

FIG. 2 is a cross-sectional view showing a configuration of a wafer mounting electrode of the plasma processing device according to the embodiment of the invention.

FIG. 3 is a cross-sectional view showing a detailed configuration of a peripheral portion of the wafer mounting electrode of the plasma processing device according to the embodiment of the invention.

FIG. 4 is a cross-sectional view showing a configuration of an insulation ring and a ring electrode of the wafer mounting electrode of the plasma processing device according to the embodiment of the invention.

FIG. 5 is a cross-sectional view of the peripheral portion of the wafer mounting electrode which shows a state of a plasma sheath in the peripheral portion of the wafer mounting electrode of the plasma processing device according to the embodiment of the invention.

### DESCRIPTION OF EMBODIMENTS

In the invention, in order to improve controllability of a ring electrode provided to surround a periphery of a substrate electrode, the ring electrode is formed of a thin film on a surface of a dielectric, a distance from the substrate electrode is set as large as possible to reduce capacitive coupling generated between the substrate electrode and the ring electrode. As a result, when high frequency power is applied from separate power supplies to the substrate electrode and the ring electrode, respectively, a degree of interference between high frequency power caused by capacitive coupling generated between the substrate electrode and the ring electrode with a distance therebetween being relatively small can be reduced, and controllability of surface potential generated by the ring electrode can be improved.

Accordingly, an influence of a sheath region formed in a vicinity of an outer peripheral portion of the substrate electrode on plasma processing uniformity is reduced, and plasma processing can be uniformly performed up to a vicinity of an outer peripheral portion of a wafer subject to processing, so that the number of non-defective devices that can be obtained from one wafer can be increased.

Further, in the invention, in order to set the distance between the substrate electrode and the ring electrode as large as possible to reduce capacitive coupling between the two electrodes, the ring electrode is formed by spraying a conductive film on a surface of a ring-shaped member formed of an insulating material surrounding the substrate electrode, but in order to prevent abnormal discharge from occurring in this conductive sprayed film during plasma processing, a film of an insulating material is sprayed and formed on the conductive sprayed film and the conductive sprayed film is covered with the film of the insulating material.

Further, the ring electrode extends not only to a plane parallel to a sample stage on a surface of an insulation ring and a wafer but also to an oblique portion facing the wafer and an insulation ring provided on an outer peripheral portion of the wafer.

With such a structure, a distortion of an electric field in the sheath region of the outer peripheral portion of the wafer can be reduced, the plasma processing uniformity up to the vicinity of the outer peripheral portion of the wafer subject to processing can be improved, and the number of non-defective devices that can be manufactured from one wafer can be increased.

Hereinafter, embodiments of the invention will be described in detail with reference to the drawings. In all the drawings for illustrating the embodiments, components having the same function are denoted by the same reference numerals, and the repetitive description thereof will be omitted in principle.

However, the invention should not be construed as being limited to the description of the embodiments described below. It will be readily understood by those skilled in the art that the specific configuration may be modified without departing from the spirit or scope of the present invention.

### First Embodiment

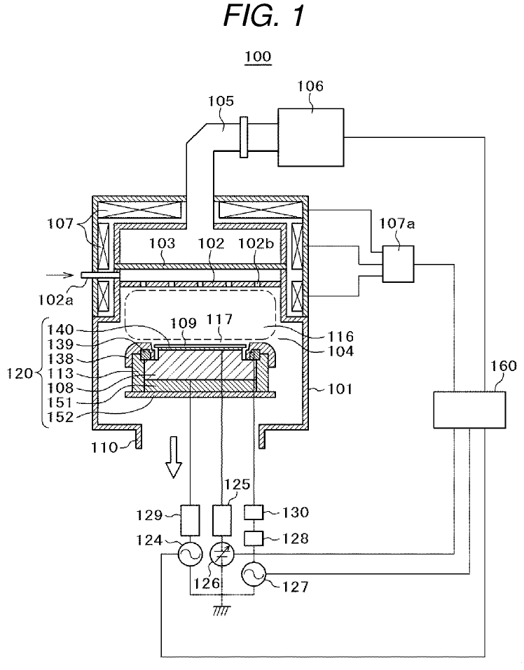

As a plasma processing device according to the embodiment, FIG. 1 shows an example of a plasma etching device 100 which is a plasma processing device that supplies a microwave to a magnetic field which satisfies an Electron Cyclotron Resonance (ECR) condition, and generates high density plasma to processes a wafer subject to processing. The plasma etching device 100 includes a vacuum container 101 which includes a processing chamber 104 where plasma is formed inside, and a dielectric window 103 that seals an upper portion of the vacuum container 101. The processing chamber 104 is formed inside the vacuum container 101 sealed by the dielectric window 103. The dielectric window 103 is formed of quartz or the like.

An exhaust port 110 is provided in a lower portion of the vacuum container 101 and is connected with an evacuation unit (not shown). On the other hand, a disk-shaped shower plate 102 which forms a ceiling of the processing chamber 104 is provided below the dielectric window 103 that seals the upper portion of the vacuum container 101. A gas supplying unit 102a that supplies gas used for etching processing from a gas supplying means (not shown) is provided between the dielectric window 103 and the shower plate 102. A plurality of gas inlet holes 102b used to supply, to the processing chamber 104, the gas used for etching processing that is supplied from the gas supplying unit 102a are formed in the shower plate 102. The shower plate 102 is formed of a dielectric such as quartz or the like.

A microwave power supply 106 and a waveguide 105 are attached to an outside the vacuum container 101, the microwave power supply 106 is used to generate microwave power which is supplied to an inside of the vacuum container 101, and the waveguide 105 is connected with the microwave power supply 106 and an upper portion of the vacuum container 101 and forms a transfer path to transfer microwave generated by the microwave power supply 106 to the vacuum container 101. For example, a microwave having a frequency of 2.45 GHz is used as the microwave generated by the microwave power supply 106.

A magnetic field generating coil 107 that generates a magnetic field is respectively provided above and outside the vacuum container 101 and is provided on the outer periphery of the vacuum container 101 at a portion where the dielectric window 103 is provided. The magnetic field generating coil 107 is connected to a magnetic field generating coil power supply 107a.

Inside the vacuum container 101, a wafer mounting electrode (a first electrode) 120 that forms a sample stage is provided in a lower portion of the processing chamber 104. The wafer mounting electrode 120 is supported inside the vacuum container 101 by a suspension part (not shown).

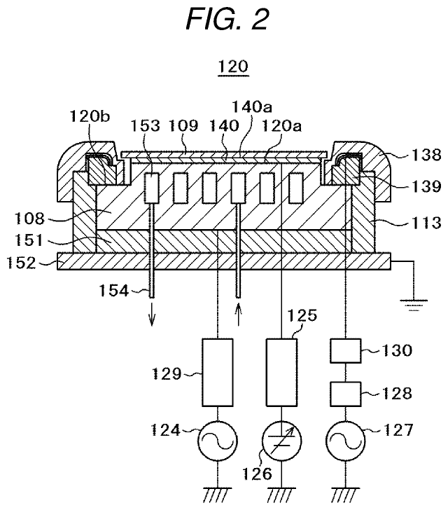

Details of the wafer mounting electrode 120 are shown in FIG. 2. The wafer mounting electrode 120 is in a state in which an electrode base material 108 formed of a conductive material, an insulating plate 151 formed of a dielectric material, and a grounding plate 152 formed of a conductive material are stacked. On an upper surface of the electrode base material 108, a peripheral portion is one step lower than a central portion, and a surface 120b is formed on the peripheral portion one step lower than an upper surface 120a of the central portion.

A periphery of the electrode base material 108 and the insulating plate 151, and the surface 120b of the electrode base material 108 are covered with a lower susceptor ring 113, an upper susceptor ring 138, and an insulation ring 139 that are formed of a dielectric material. The upper susceptor ring 138 covers an upper surface and a side surface of the insulation ring 139 provided on the surface 120b of the electrode base material 108.

Ceramics, quartz, or the like is used as a dielectric material that forms the insulating plate 151, the lower susceptor ring 113, the upper susceptor ring 138, and the insulation ring 139.

The upper surface 120a of the electrode base material 108 is covered with a dielectric film 140, and a surface of the dielectric film 140 is a mounting surface 140a where a sample (a semiconductor wafer) 109 which is a processing target is mounted. As shown in FIG. 1, the mounting surface 140a faces the shower plate 102 and the dielectric window 103.

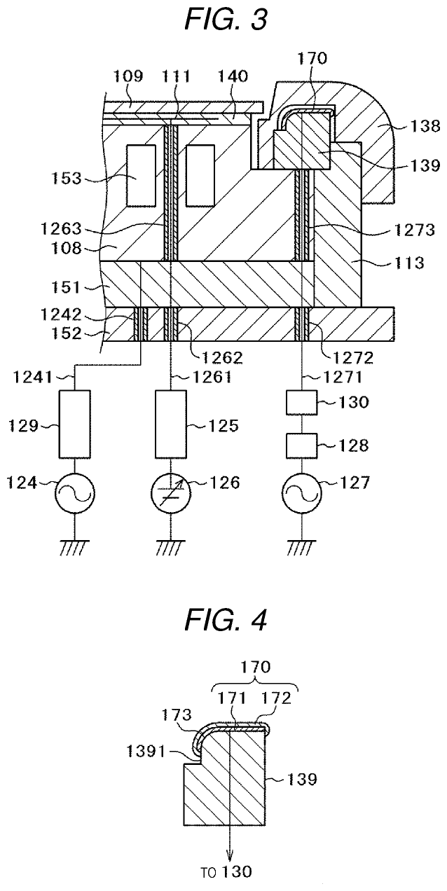

As shown in FIG. 3, a plurality of electrostatic adsorption electrodes (conductor films) 111 are formed in the dielectric film 140 which is formed on the upper surface 120a of the wafer mounting electrode 120. The electrostatic adsorption electrode 111 is connected with a DC power supply 126 via a high frequency filter 125 provided outside the vacuum container 101 by a power supply line 1261. The power supply line 1261 is insulated from the grounding plate 152 and the electrode base material 108 by passing through an inside of an insulating pipe 1262 in a portion of the grounding plate 152 and passing through an inside of an insulating pipe 1263 in a portion of the electrode base material 108.

In a configuration shown in FIG. 3, although the electrostatic adsorption electrode 111 is a monopolar configuration connected with one DC power supply 126 via the high frequency filter 125, a plurality of DC power supplies 126 may be used to form a bipolar configuration in which different polar potentials are supplied to the plurality of electrostatic adsorption electrodes (conductor films) 111.

The electrode base material 108 of the wafer mounting electrode 120 is connected with a first high frequency power supply 124 via a matching device 129 by a power supply line 1241. One end of the first high frequency power supply 124 is grounded. The power supply line 1241 is insulated from the grounding plate 152 by passing through an inside of an insulating pipe 1242 in a portion of the grounding plate 152.

Further, inside the electrode base material 108, a refrigerant flow path 153 that allows a refrigerant supplied from a refrigerant supplying unit (not shown) to flow is spirally formed around a center axis of the electrode base material 108 in order to cool the electrode base material 108. The refrigerant is circulated inside the refrigerant flow path 153 by supplying and collecting the refrigerant from the refrigerant supplying unit (not shown) to the refrigerant flow path 153 via a pipe 154.

An outer diameter of the upper surface 120a of the wafer mounting electrode 120 (the upper surface of the electrode base material 108) is slightly smaller than an outer diameter of the sample (semiconductor wafer) 109 mounted on the mounting surface 140a. As a result, as shown in FIGS. 2 and 3, an outer peripheral portion of the sample (semiconductor wafer) 109 extends slightly beyond the mounting surface 140a in a state in which the sample (semiconductor wafer) 109 is mounted on the mounting surface 140a.

The surface 120b of the outer peripheral portion around the upper surface 120a of the wafer mounting electrode 120 is formed to be one step lower than the upper surface 120a. As shown in FIG. 2, the upper susceptor ring 138 and the insulation ring 139 are mounted on the surface 120b of the outer peripheral portion. The lower susceptor ring 113 covers a side surface of the insulating plate 151 on a lower side of the wafer mounting electrode 120 from a side surface of the wafer mounting electrode 120. The upper susceptor ring 138 and the lower susceptor ring 113 cover an outer peripheral surface of the electrode base material 108 and the surface 120b of the outer peripheral portion.

In a region surrounded by the upper susceptor ring 138 and the insulation ring 139, the insulation ring 139 is provided on the surface 120b of the outer peripheral portion of the wafer mounting electrode 120 to surround the side surface of the wafer mounting electrode 120. A ring electrode 170 is formed on a portion of an upper surface and an inner surface of the insulation ring 139.

Details of the ring electrode 170 are shown in FIG. 4. The ring electrode 170 includes a thin film electrode 171 formed on an upper surface of the insulation ring 139 and on a portion of an inner surface of the insulation ring 139 facing a side of the electrode base material 108, and a thin film of a dielectric film 172 that covers a surface of the thin film electrode 171. As shown in FIGS. 2 and 3, the thin film electrode 171 is connected with a second high frequency power supply 127 via a load impedance variable box 130 and a matching device 128 by a power supply line 1271. The power supply line 1271 is insulated from the grounding plate 152 and the electrode base material 108 by passing through an inside of an insulating pipe 1272 in a portion of the grounding plate 152 and passing through an inside of an insulating pipe 1273 in a portion of the electrode base material 108.

The microwave power supply 106, the magnetic field generating coil power supply 107a, the first high frequency power supply 124, the DC power supply 126, and the second high frequency power supply 127 are respectively connected to a control unit 160 and are controlled according to a program stored in the control unit 160.

In such a configuration, first, the sample (semiconductor wafer) 109 is mounted on the upper surface 120a of the wafer mounting electrode 120 by using a sample supplying unit (not shown). Next, in a state in which the vacuum container 101 is sealed, the control unit 160 operates the exhaust unit (not shown) to evacuate the inside of the vacuum container 101 through the exhaust port 110.

When the inside of the vacuum container 101 reaches predetermined pressure by evacuation, the control unit 160 operates the gas supplying means (not shown) to supply, at a predetermined flow rate, gas used for etching processing from the gas supplying unit 102a to a space between the dielectric window 103 and the shower plate 102. The gas used for etching processing supplied to the space between the dielectric window 103 and the shower plate 102 flows into the processing chamber 104 through a plurality of gas inlet holes 102b formed in the shower plate 102.

Next, in a state in which the gas used for etching processing is supplied and the inside of the processing chamber 104 is kept at predetermined pressure, the control unit 160 controls the DC power supply 126 to apply a DC voltage to the electrostatic adsorption electrode (conductor film) 111 via the power supply line 1261. Accordingly, static electricity is generated on the surface (mounting surface 140a) of the dielectric film 140 which covers the electrostatic adsorption electrode (conductive film) 111, and the sample (semiconductor wafer) 109 is electrostatically adsorbed on the surface (mounting surface 140a) of the dielectric film 140.

In a state in which the sample (semiconductor wafer) 109 is electrostatically adsorbed on the surface (mounting surface 140a) of the dielectric film 140, the control unit 160 controls the gas supplying means (not shown), and gas (for example, helium (He) or the like) used for heat transfer is supplied from a side of the wafer mounting electrode 120 to a space between the surface (mounting surface 140a) of the dielectric film 140 formed on the surface of the wafer mounting electrode 120 and the sample (semiconductor wafer) 109.

Further, the control unit 160 controls the refrigerant supplying unit (not shown) to supply and collect the refrigerant from the pipe 154 to the refrigerant flow path 153 to circulate the refrigerant inside the refrigerant flow path 153 so as to cool the electrode base material 108.

The sample (semiconductor wafer) 109 mounted on the cooled electrode base material 108 is electrostatically adsorbed on the surface of the dielectric film 140, and in a state in which the gas used for etching processing is supplied and the inside of the processing chamber 104 reaches predetermined pressure, the control unit 160 controls the magnetic field generating coil power supply 107a to generate a desired magnetic field inside the processing chamber 104. Further, the control unit 160 controls the microwave power supply 106 to generate a microwave, and the generated microwave is supplied to the inside of the vacuum container 101 via the waveguide 105.

Here, the magnetic field generated inside the processing chamber 104 by the magnetic field generating coil power supply 107a is formed to have a strength that satisfies the ECR condition with respect to the microwave supplied from the microwave power supply 106. Accordingly, the gas used for etching processing which is supplied to the inside of the processing chamber 104 is excited to generate high density plasma of the gas used for etching processing.

On the other hand, the control unit 160 controls the first high frequency power supply 124 to generate high frequency power and apply the high frequency power to the electrode base material 108 via the matching device 129 so as to generate a bias potential on the electrode base material 108 with respect to plasma 116. The control unit 160 controls the first high frequency power supply 124 to adjust the bias potential generated on the electrode base material 108, so that energy of charged particles such as ionized etching gas drawn from the plasma 116 having a relatively high density to a side of the electrode base material 108 can be controlled.

The charged particles generated by the gas used for etching processing with controlled energy collide with the surface of the sample (semiconductor wafer) 109 mounted on the electrode base material 108. Here, a mask pattern is formed on the surface of the sample (semiconductor wafer) 109 by a material that does not or that is difficult to react with the gas used for etching processing, and a portion that is not covered with the mask pattern on the surface of the sample (semiconductor wafer) 109 is etched.

During etching processing, the gas used for etching processing which is introduced into the processing chamber 104 and reactive biological particles which are generated by etching processing are discharged to the outside through the exhaust port 110 by the vacuum exhaust unit (not shown).

During the etching processing, the sample 109 whose surface collides with the charged particles generated by the gas used for etching processing generates heat. The heat generated by the sample 109 is transferred, by the gas used for heat transfer that is supplied from the gas supplying means (not shown) to the space between the dielectric film 140 formed on the surface of the wafer mounting electrode 120 and the sample 109, from the back surface side of the sample 109 to the side of the electrode base material 108 which is cooled by the refrigerant flowing inside the refrigerant flow path 153. Accordingly, a temperature of the sample 109 is adjusted within a desired temperature range. In this state, the etching processing is performed on the surface of the sample 109, so that a desired pattern is formed on the surface of the sample 109 without thermally damaging the sample 109.

With regard to the etching processing on the surface of the sample 109, if an incidence mount and direction of the charged particles such as the gas used for etching processing which enters onto the surface of the sample 109 from the plasma 116 are uniform throughout an entire surface of the sample 109, the surface of the sample 109 is substantially processed uniformly.

However, in practice, in order to prevent the electrode base material 108 of the wafer mounting electrode 120 formed of a conductive material from being exposed to the plasma 116, the outer peripheral portion of the electrode base material 108 is covered with the lower susceptor ring 113, the upper susceptor ring 138, and the insulation ring 139 which are formed of a dielectric material, so that a difference in shape and electric field distribution of a sheath region 117 which is formed between plasma 116 and the wafer mounting electrode 120 occurs in the center portion and the outer peripheral portion of the electrode base material 108.

Thus, since the difference in shape and electric field distribution of the sheath region 117 occurs in the central portion and the outer peripheral portion of the electrode base material 108, an electric field generated in the sheath region 117 between the sample 109 and the plasma 116 is not uniform on the central portion which is relatively apart from the upper susceptor ring 138 and on the peripheral portion which is relatively close to the upper susceptor ring 138, and a distribution occurs on the upper surface of the sample 109 mounted on the wafer mounting electrode 120. As a result, the conditions of etching processing (an incidence amount and direction of the charge particles) are different in the vicinity of the central portion and the vicinity of the peripheral portion of the sample 109 so that etching cannot be performed uniformly, and a distribution of etching processing occurs on the surface of the sample 109.

Corresponding to this, in the present embodiment, as shown in FIG. 4, a thin film electrode 171 is formed on an upper surface of the surface and a part of an inner surface of the insulation ring 139 that is provided around the electrode base material 108, and high frequency power from the second high frequency power supply 127 is applied to the thin film electrode 171 via the matching device 128 and the load impedance variable box 130, so that a difference in electric field distribution generated in the central portion and the peripheral portion of the surface of the sample 109 is reduced as much as possible.

The second high frequency power supply 127 is a power supply different from the first high frequency power supply 124 that applies high frequency power to the electrode base material 108, and applies power independent from the high frequency power applied to the electrode base material 108 to the thin film electrode 171.

Here, Patent Literature 2 discloses that high frequency power is efficiently contributed to an outer peripheral portion or an outer peripheral edge portion of a wafer by applying high frequency power from a high frequency power supply to a conductor ring whose surface is covered with a susceptor ring formed of a dielectric material.

However, capacitive coupling occurs between the conductor ring and a metallic base material. Although coupling capacity C generated by the capacitive coupling between the conductor ring and the base material varies according to a dielectric constant and a thickness of an insulator interposed between the conductor ring and the base material, since the conductor ring is formed with a certain thickness, a thickness of the interposed insulator needs to be reduced by the thickness of the conductor ring when a position in the height direction is limited to the conductor ring. Therefore, in order to reduce the coupling capacity C between the conductor ring and the base material, there is a limit caused by the thickness of the insulator.

As a result, in the configuration of Patent Literature 2, when high frequency power is independently applied from separate power supplies to the conductor ring and a base material which is an electrode, relatively small high frequency power applied to the conductor ring is influenced by relatively large high frequency power applied to the base material which is an electrode by capacitive coupling between the conductor ring and the base material, controllability of an electric field generated around the conductor ring is reduced, and a desired electric field distribution may not be obtained.

In contrast, in the present embodiment, as shown in FIG. 4, the function corresponding to the conductor ring disclosed in Patent Literature 2 is implemented by the ring electrode 170 formed on the surface of the insulation ring 139 that is formed of a dielectric material. That is, in the present embodiment, the thin film electrode 171 is formed as the ring electrode 170 on the surface of the insulation ring 139, and the surface is covered with the dielectric film 172, so that a distance from the surface 120b of the outer peripheral portion of the electrode base material 108 in the present embodiment is configured to be increased by an amount corresponding to the thickness of the conductor ring in Patent Literature 2 with respect to the configuration disclosed in Patent Literature 2.

Accordingly, the coupling capacity C between the thin film electrode 171 and the surface 120b of the outer peripheral portion of the electrode base material 108 in the present embodiment can be smaller than the coupling capacity between a portion of the base material corresponding to the surface 120b in the present embodiment and the conductor ring disclosed in the configuration in Patent Literature 2.

As a result, in the present embodiment, when high frequency power is independently applied from separate high frequency power supplies to the thin film electrode 171 and the base material 108, since the influence of relatively large high frequency power applied to the base material 108 by the capacitive coupling between the thin film electrode 171 and the electrode base material 108 on relatively small high frequency power applied to the thin film electrode 171 can be reduced, the electric field formed around the thin film electrode 171 can be stably controlled.

Further, since the surface of the thin film electrode 171 is covered with the dielectric film 172, when plasma is generated inside the processing chamber 104 and the second high frequency power from the second high frequency power supply 127 is applied to the thin film electrode 171, abnormal discharge in the thin film electrode 171 can be prevented from occurring and a disorder in shape of the sheath region and in electric field distribution in the sheath region in the periphery portion of the sample 109 can be prevented from occurring.

The thin film electrode 171 is formed of a thin film of tungsten by spraying tungsten (W) on the surface of the insulation ring 139. The dielectric film 172 is formed of a thin film of alumina by spraying alumina to cover a portion where the thin film of tungsten is sprayed on the surface of the insulation ring 139.

Further, a portion 173 where an upper surface of the insulation ring 139 intersects an inner side surface which is connected to the upper surface is formed into an R shape with a rounded corner as shown in FIG. 4. Since the thin film electrode 171 is formed on the upper surface and the inner side surface which is connected to the upper surface of the insulation ring 139, including the portion formed into the R shape with the rounded corner, when high frequency power is applied to the thin film electrode 171, an electric field can be prevented from concentrating on the portion formed into the R shape with the rounded corner. By preventing the concentration of electric field in this way, the shape of the sheath region and the electric field distribution in the sheath region on the peripheral portion of the sample 109 cannot be influenced, or the influence can be reduced.

The control unit 160 controls the second high frequency power supply 127 to apply second high frequency power to the thin film electrode 171 of the ring electrode 170 formed in this way via the load impedance variable box 130 and the matching device 128 by the power supply line 1271. At the same time, the first high frequency power from the first high frequency power supply 124 is applied to the electrode base material 108 via the matching device 129 by the power supply line 1241.

Here, the coupling capacity C generated by the capacitive coupling between the thin film electrode 171 and the surface 120b of the outer peripheral portion of the electrode base material 108 is in proportion to an area of the thin film electrode 171 facing the surface 120b of the outer peripheral portion of the electrode base material 108, and is in inverse proportion to the distance between the surface 120b of the outer peripheral portion of the electrode base material 108 and the thin film electrode 171.

In the configuration of the ring electrode 170 shown in FIG. 4, although the thin film electrode 171 is also formed on an upper portion of a left side surface 1391 of the insulation ring 139, since, in this portion, an area of a portion where the thin film electrode 171 faces a side surface of the electrode base material 108 is sufficiently small compared with an area of a portion facing the surface 120b of the outer peripheral portion of the electrode base material 108, the capacitive coupling generated between the thin film electrode 171 and the electrode base material 108 can be considered to be dominated by the coupling capacity C generated by the capacitive coupling between the thin film electrode 171 and the surface 120b of the outer peripheral portion of the electrode base material 108.

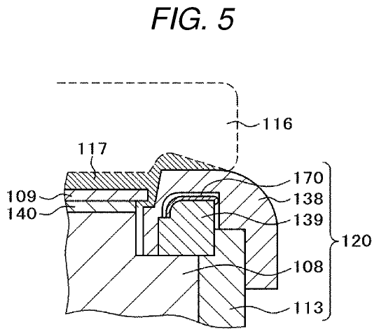

With such a configuration, the control unit 160 controls the second high frequency power supply 127 so that, as shown in FIG. 5, the sheath region 117 formed between the sample 109 and the plasma 116 in a portion across from the peripheral portion of the sample 109 to the upper susceptor ring 138 can be stably formed in the vicinity of the outer peripheral portion of the wafer mounting electrode 120 with less temporal variation in shape caused by influence of the first high frequency power.

Further, since the thin film electrode 171 is formed on the upper surface and the inner side surface of the insulation ring 139, including a portion where the corner portion of the insulation ring 139 is rounded, a distortion of the electric field on the outer peripheral portion of the sample 109 mounted on the wafer mounting electrode 120 can be reduced without generating concentration of the electric field. As a result, the electric field distribution of the sheath region 117 of the plasma 116 formed on the upper surface of the sample 109 can be substantially unified from the central portion to the peripheral portion of the sample 109.

Accordingly, an incidence direction of the charged particles from the plasma 116 that enter from the central portion to the peripheral portion of the sample 109 can be substantially the same, and a shape of the pattern formed by etching on the sample 109 can be prevented from varying in the vicinity of the central portion and in the vicinity of the peripheral portion of the sample 109.

Further, local consumption of the upper susceptor ring 138 does not occur and life of the upper susceptor ring 138 can be prolonged by eliminating the concentration of the electric field. As a result, the replacement frequency of the upper susceptor ring 138 can be reduced and a device operation rate of the plasma etching device 100 can be increased.

In the present embodiment described above, although the ring electrode 170 is formed of a conductor thin film by spraying tungsten (W) onto the surface of the insulation ring 139 formed of a dielectric material, and a dielectric film 172 is formed on the conductor thin film by spraying alumina, instead of the conductor thin film formed by spraying tungsten (W), a thin metallic plate molded along the surface of the insulation ring 139 may be used, and a film formed by spraying alumina on the surface of the thin metallic plate may be used.

According to the present embodiment, since plasma processing can be performed uniformly up to the outer peripheral portion of the wafer, the wafer can be uniformly processed on the surface and the yield of a semiconductor element can be improved.

Further, since the electric field can be prevented from concentrating on the upper susceptor ring 138 which is provided on the outer peripheral portion of the electrode base material 108 of the wafer mounting electrode 120 and directly exposed to plasma, the life of the upper susceptor ring 138 can be prolonged.

While the invention has been described in detail based on the embodiments, the invention is not limited to the above-described embodiments, and various modifications can be made without departing from the scope of the invention. For example, the embodiments described above have been described in detail for easy understanding of the invention, and the invention is not necessarily limited to those including all the configurations described above. In addition, a part of the configuration of the embodiment may be added, deleted, or replaced with a known configuration.

What is claimed is:

1. A plasma processing device, comprising:
a vacuum container;
a mounting table that includes an electrode base material where a sample subject to processing is mounted inside the vacuum container, a susceptor ring that is formed of an insulating material that covers an outer peripheral portion of the electrode base material, and an insulation ring that is covered by the susceptor ring, is disposed to surround an outer periphery of the electrode base material, and has a thin film electrode formed on an upper surface and a part of a surface facing the outer periphery of the electrode base material;
a first high frequency power applying unit that applies a first high frequency power to the electrode base material of the mounting table;
a second high frequency power applying unit that applies a second high frequency power to the thin film electrode formed on the insulation ring;
a plasma generating unit that generates plasma on an upper portion of the mounting table inside the vacuum container; and
a control unit that controls the first high frequency power applying unit, the second high frequency power applying unit, and the plasma generating unit.

2. The plasma processing device according to claim 1, wherein
a surface of the thin film electrode is covered with a dielectric film.

3. The plasma processing device according to claim 2, wherein
the thin film electrode is formed of a tungsten film, and the dielectric film is formed of alumina.

4. The plasma processing device according to claim 3, wherein
the tungsten film of the thin film electrode is formed by spraying tungsten onto a surface of the insulation ring.

5. The plasma processing device according to claim 3, wherein
an alumina film that covers the surface of the thin film electrode is formed by spraying alumina to cover a portion of the insulation ring where the tungsten film is formed.

6. The plasma processing device according to claim 1, wherein
in portions where the thin film electrode of the insulation ring is formed, a portion where an upper surface of the insulation ring intersects the surface facing the outer periphery of the electrode base material is connected by a rounded surface.

7. The plasma processing device according to claim 1, wherein
the mounting table has a stepped shape in which a peripheral portion is recessed with respect to a central portion, and the insulation ring is covered by the susceptor ring in a state of being mounted on a step-shaped portion where the peripheral portion of the mounting table is recessed.

8. The plasma processing device according to claim 1, wherein
the plasma generating unit includes:
a dielectric window that is provided on an upper portion of the vacuum container and opposite to the mounting table and is formed of a dielectric material;
a power supply unit that supplies high frequency power from the upper portion of the vacuum container to an inside of the vacuum container via the dielectric window; and
a magnetic field generating unit that is provided outside the vacuum container and generates a magnetic field inside the vacuum container.
